(19) United States
(12) Patent Application Publication
(10) Pub. No.: US 2026/0104459 A1
(43) Pub. Date: Apr. 16, 2026

(54) SYSTEMS AND METHODS FOR MONITORING ENERGY CONSUMPTION OF TASKS PERFORMED BY A HEAVY MACHINE

(71) Applicant: Podco Inc., Sudbury (CA)

(72) Inventors: Stephen Alexis PODRUCKY, Iroquois Falls (CA); Kevin Richard REYNEN, Sudbury (CA)

(73) Assignee: Podco Inc., Sudbury, ON (CA)

(21) Appl. No.: 18/911,801

(22) Filed: Oct. 10, 2024

(51) Int. Cl. G01R 31/36; G01R 15/20; G01R 31/3842; G07C 5/00; H01M 10/42; H01M 10/48

(52) U.S. Cl. CPC G01R 31/3648; G01R 15/202; G01R 31/3842; G07C 5/008; H01M 10/425; H01M 10/48; H01M 2010/4271; H01M 2220/20

(57) ABSTRACT

Methods and systems for monitoring battery consumption for a heavy machine such as used in mining, construction, agriculture, and/or industrial applications is provided. The system for reporting a state of charge of a heavy machine has a sensor or input device determining a start and an end of a task; a battery monitor coupled to a battery, the battery monitor measuring a battery charge in the battery; a display; and a processor coupled to the display, the sensor or the input device, and to the battery monitor. The processor or method may determine a change in the battery charge used by the heavy machine between the start and the end of the task to provide a task charge; determine a number of remaining tasks from the battery charge and the task charge; and present the number of remaining tasks on the display.

### FIELD

The present invention relates generally to monitoring energy consumption of emission-less heavy machinery. More particularly, the present invention relates to methods and systems for monitoring and displaying battery consumption associated with one or more tasks for a heavy machine such as used in mining, construction, agriculture, and/or industrial applications.

### BACKGROUND

Japanese U.S. Pat. No. 5,599,337 B2 to Yasumoto discloses a device for indicating remaining battery power of an electric car configured to indicate the remaining battery power of the electric car in the form of the number of times or the like the vehicle can make a round trip to nearby facilities. When the electric car is powered up, a list of nearby favorite facilities is displayed. How many times the car can make a round trip to each of the facilities with the current battery capacity is displayed, or frequently used routes from the current location are displayed together with the possible number of trips based on the current battery capacity in a list. The current battery capacity can be intuitively displayed in relation to the favorite facilities or the routes. The information in the list can be displayed in the order of the possible number of trips or the number of trips based on travel history data stored on a regular basis. The information can be displayed in a conventional manner that displays a possible travel distance or a possible round-trip distance based on the current battery capacity.

U.S. Pub. No. 2023/150394 A1 to Diamond et al. discloses systems and methods for adaptive prediction of electrified vehicle performance including receiving a set of goal parameters identifying a drivers performance requirements, receiving a set of fixed parameters related to course, vehicle and passenger status, receiving past energy consumption data for the electrified vehicle and the driver, generating an adaptive prediction of a future state of charge (SOC) of one or more electricity sources, and providing a dynamic control alteration based on the adaptive prediction, the dynamic control alteration as a function of the set of goal parameters. The adaptive prediction is based on the set of goal parameters, the set of fixed parameters and the past energy consumption data. The adaptive prediction includes updated parameters based on performance of the electrified vehicle.

U.S. Pat. No. 11,479,142 B1 to Govan et al. discloses a system receiving historical vehicle battery data from a gateway device connected to a vehicle. Some vehicles with plug-in rechargeable batteries recommend/require that the vehicle computer be turned off when recharging. Thus, obtaining a current state of charge while a vehicle is charging can be difficult because the vehicle computer can be off. While the vehicle/gateway device is unable to transmit current battery data, the systems estimate a battery charge from the historical data.

### SUMMARY

Any and/or all aspects as described herein in any and/or all combinations are described.

According to an aspect, there is provided a system for reporting a state of charge of an electric machine, the system may comprise: a sensor or input device determining a start and an end (e.g., duration) of a task; a battery monitor coupled to a battery, the battery monitor measuring a battery charge in the battery; a processor coupled to the battery monitor, the processor configured to execute instructions from a computer-readable memory to: determine a change in the battery charge during the task to provide a task charge; and determine a number of remaining tasks from the battery charge and the task charge. In some aspects, the instructions may further comprise: presenting the number of remaining tasks on a display and/or providing any other indicator of the remaining tasks to the operator. The task may be travel to or from at least one waypoint. The task charge may be different depending on a direction travelled from or to the at least one waypoint and/or proximity to a waypoint. The sensor may be selected from at least one of: a global positioning sensor (GPS), at least one magnetometer, a cellular triangulation, an altimeter, a tilt sensor, a wireless receiver and at least one wireless beacon, and at least one accelerometer. The instructions may further comprise: reserving a reserve of the battery charge so that the electric machine can reach a charging station. The battery monitor may comprise at least one of: a current sensor measuring one or more current measurements; and a voltage sensor measuring one or more voltage measurements. The current sensor may measure the current measurements without disconnecting the battery. The current sensor may be a hall-effect sensor. A server computer system may receive at least one of: a task type, the task duration, and the task charge from the processor. The instructions may further comprise computing a power from the current measurements and the voltage measurements; and integrating the power for the task duration. The processor may determine the number of the remaining tasks based on the task charge of a plurality of tasks; and may presents the number of remaining tasks separately on the display.

According to another aspect, there is provided a method for reporting a state of charge of an electric machine, the method comprising: measuring a battery charge using a battery monitor coupled to a battery; determining a change in the battery charge during the task to provide a task charge; and determining a number of remaining tasks from the battery charge and the task charge. In some aspects, the method may present the number of remaining tasks on a display. The task may be travel to or from at least one waypoint. The task charge for a plurality of the tasks may may be different depending on the task and may be presented as a list of tasks on the display. A sensor or an input device may determine the duration of the task. The sensor may be selected from at least one of: a global positioning sensor (GPS), at least one magnetometer, a cellular triangulation, an altimeter, a tilt sensor, a wireless receiver and at least one wireless beacon, and at least one accelerometer. The method may reserve a reserve of the battery charge for the electric machine to reach a charging station. The battery monitor may comprise at least one of: a current sensor measuring one or more current measurements; and a voltage sensor measuring one or more voltage measurements. The current sensor may measure the current measurements without disconnecting the battery. The current sensor may be a hall-effect sensor. A server computer system may receive at least one of: a task type, the task duration, and the task charge. The method may further comprise computing a power from the current measurements and the voltage measurements; and may integrate the power for the task duration. The method may determine the number of the remaining tasks based on the task charge of a plurality of the tasks; and may present the number of remaining tasks separately on a display.

### BRIEF DESCRIPTION OF THE DRAWINGS

An embodiment will now be described, by way of example only, with reference to the attached Figures, wherein:

FIG. 1 is a block diagram demonstrating an electronic vehicle with a battery monitoring system;

FIG. 2 is a block diagram demonstrating the battery monitoring system;

FIG. 3 is a block diagram demonstrating a non-invasive battery monitoring system;

FIG. 4 is a block diagram of a processing system for the battery monitoring system;

FIG. 5 is a flow chart for a process of battery monitoring;

FIG. 6 is a block diagram of a waypoint system;

FIG. 7 is a flowchart for a process of waypoint determination; and

FIG. 8 is a flowchart for a process of waypoint dead reckoning.

### DETAILED DESCRIPTION

Heavy machine 120 for mining (open pit or otherwise), construction, agriculture, and/or industrial equipment may include an energy storage 102 and a vehicle electronic system 108. The energy storage 102 may provide energy to operate the heavy machine 120, such as to move the heavy machine 120 from one location to another, and/or accomplish any number of tasks. As described herein, the energy storage 102 may provide electrical energy to power one or more electric loads. In the aspects described herein, the electric load is one or more motors 122 (e.g. or engines) through an electrical circuit. Other aspects may have the electric load be a resistive load, such as a heater and/or the vehicle electronic system 108. Herein, energy storage 102 and battery 102 may be used interchangeably. The motors 122 may operate wheels, tracks, valves (e.g. for hydraulics), and/or any other type of actuator (not shown) to accomplish the tasks. For example, the heavy machine 120 may lift materials or move materials from one location to another. Examples of the heavy machine 120 in a mining application may comprise scoops for bringing loose rock from a rock face), haulage trucks (e.g., dump trucks), auxiliary equipment (e.g., bolters that drill into rock to put up screens), scissor lifts for construction crews, cassette trucks, man carriers (e.g., jeeps, etc.), and/or other types of trucks.

Previously, the heavy machine 120 used fossil fuels, such as diesel, stored in a fuel tank as the energy storage 102 that provides the fuel to a diesel engine. Diesel vehicles create fumes that cause a number of health problems, such as lung cancer. These fumes are particularly problematic when the heavy machine 120 is used in mining. The fumes may require costly and/or complex ventilation systems to remove the fumes from the mine. Even using these ventilation systems does not remove all the fumes. Transitioning to emission-less energy sources, such as vehicle batteries 102, may reduce ventilation system requirements. Even where the heavy machine 120 operates in open air scenarios, using vehicle batteries 102 may provide a number of other advantages, such as reducing greenhouse gas (GHG) emissions that may be necessary to obtain government approvals and/or avoid or reduce carbon-related expenses, such as carbon taxes.

When the conventional heavy machine 120 consumes all the fossil fuel, the heavy machine 120 is provided with additional fuel. Typically providing additional fuel consumes little time as the fuel tank may be filled in a matter of minutes. However, some energy sources 102 are not able to be replenished with energy from an energy source 124 in a convenient amount of time. For example, considerable time may be necessary to charge the battery 102 to a full charge from an electrical source 124. In some cases, the amount of time to charge the battery 102 from about 5% to about 80% may take less time than to charge the battery 102 from 80% to 100%. Charging the battery 102 to 100% may be reserved for times where no work is to be performed.

For passenger electric vehicles, the charge in the battery 102 may correlate to a distance travelled. However, in industries described herein, the charge in the energy storage 102 may not be reflective of the distance travelled. For example, the distance that a haulage truck may travel per unit of charge may be dependent on a quantity of material being hauled. In another example, a digger may be mostly stationary and may be lifting material. In yet another example, operators may often repeatedly travel between two points, such as a point deeper in a mine and a point outside of the mine. In the industries described herein, the amount of charge in the battery 102 (or the distance travelled) may have little relevance to an operator of the heavy machine 120. The operator typically desires to know when the energy source 102 of the heavy machine 120 is able to accomplish an expected number of tasks (or expected trips) and/or how many of the expected tasks (or expected trips) are remaining (i.e., remaining tasks).

Systems and methods described herein may track one or more conditions applicable to emission-less energy sources, such as a battery. For example, a tracking of battery data may provide an indication of when the battery requires maintenance, charging, and/or the number of tasks able to be performed on a given amount of charge, etc. The tracking systems and methods may be complicated as the heavy machine 120 may be provided by different manufacturers of which each may provide different tracking capabilities, unique interfaces, and/or applications. The heavy machine 120 also may be relatively expensive and operators may desire not to be locked-in to a proprietary technology provided by a single manufacturer. A single manufacturer may also not be able to provide all the desired heavy machine 120 for a particular application (e.g. mining). For example, a manufacturer of dump trucks may not necessarily manufacture precision mining equipment. Manufacturers may also prevent access to some data to customers as certain data may expose them to liability for warranty claims. In other aspects, some data may not be readily available from manufacturers.

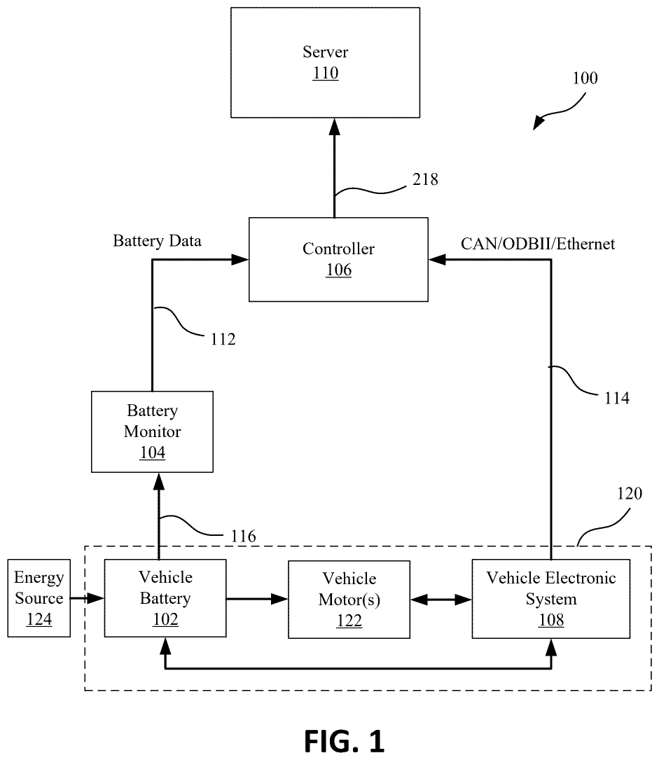

Turning to FIG. 1, there is provided an energy usage monitoring system 100 for measuring and tracking battery data (e.g. monitoring) from the heavy machine 120. As previously mentioned, the heavy machine 120 may comprise a rechargeable vehicle battery 102 providing electricity to one or more vehicle motors 122 and being periodically charged from the energy source 124. A vehicle electronic system 108 may monitor the vehicle motors 122, vehicle battery 102, and/or other vehicle parameters for the heavy machine 120. The vehicle electronic system 108 may provide a vehicle network 114 to provide vehicle data to the controller 106. In this aspect, the vehicle network 114 may be a Controller Area Network (CAN), On-Board Diagnostics Generation Two (ODB-II), Ethernet, and/or other communication interfaces.

A controller 106 may communicate with the vehicle network 114 to retrieve the vehicle data from the vehicle electronic system 108. In particular, the controller 106 may retrieve, if available, a battery %, charge data, a velocity, a battery condition, battery charge cycles, an instantaneous battery current, an instantaneous battery power, a total recovered energy (e.g., regeneration), a total energy charged to the battery, and/or a remaining time to full battery charge. The controller 106 may retrieve battery data 112, such as sensor data, from one or more battery monitors 104, such as a current sensor and/or a voltage sensor. In this aspect, the battery monitor 104 may perform analog measurements 116 from the vehicle battery 102. The battery monitor 104 may convert the analog measurements 116 into the battery data 112. In other aspects, the controller 106 may receive the analog measurements 116 and have an analog-to-digital converter within the controller 106 to convert the analog measurements 116 into the battery data 112. In some aspects, the analog-to-digital converter may be a discrete ADC between the battery monitor 104 and the controller 106.

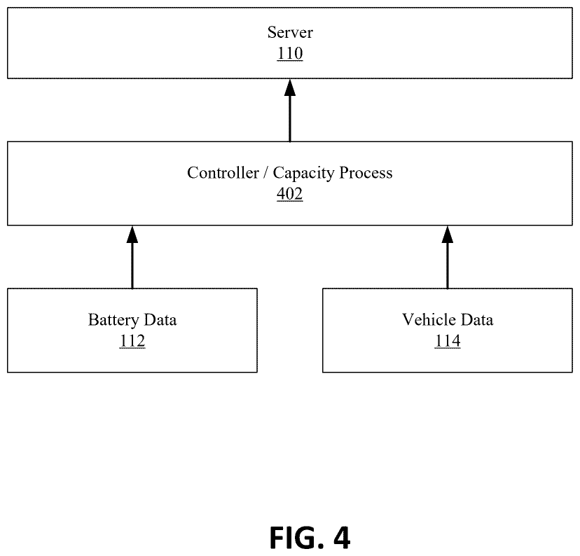

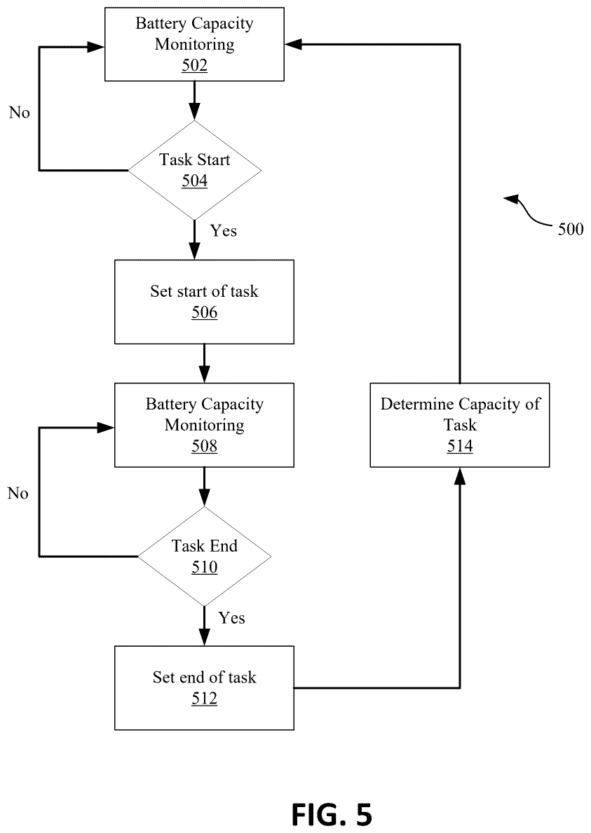

The controller 106 may communicate with a server computer system 110, hereinafter referred to as a server 110, over a communication system 218, such as a wireless network or a wired network. The controller 106 may communicate a task type, the vehicle data 114, the battery data 112, and/or any processed data to the server 110, or vice-versa. The task type may be provided by the operator of the vehicle using the user interface, such as by text entry and/or selection from a menu of predetermined tasks associated with the heavy machine. The controller 106 and/or the server 110 may process the vehicle data 114 and the battery data 112 to determine one or more tasks. The process 500 may be described in further detail with reference to FIGS. 4 and 5 below.

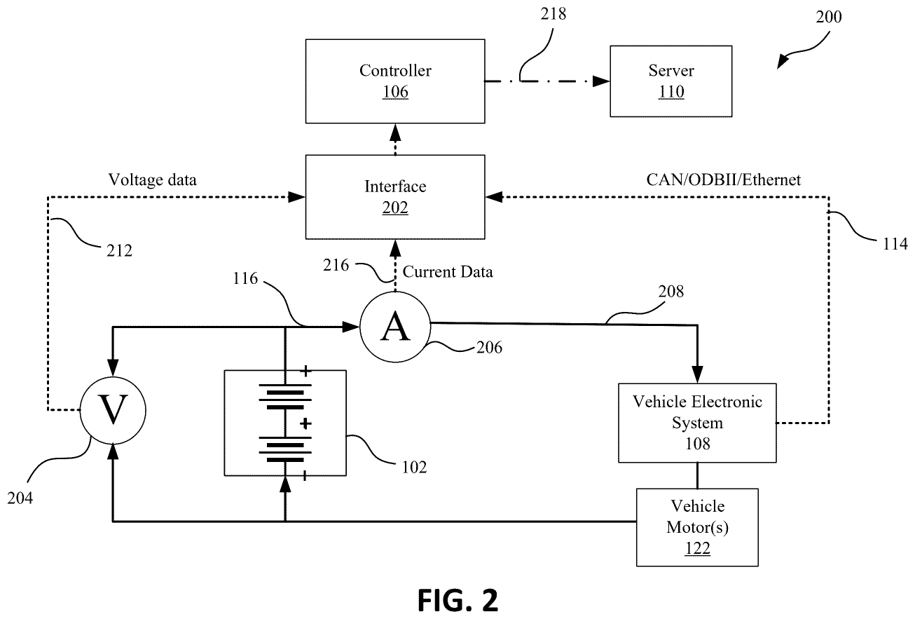

With reference to FIG. 2, there is provided another energy usage monitoring system 200 for measuring and tracking battery data from the heavy machine 120. Similar to that of FIG. 1, the heavy machine 120 may comprise the vehicle battery 102 providing electricity to the vehicle motors 122 and being periodically charged from the energy source 124. The vehicle electronic system 108 may monitor the electric loads (e.g. vehicle motors 122), vehicle battery 102, and/or other vehicle parameters for the heavy machine 120. The vehicle electronic system 108 may provide the vehicle network 114 to provide vehicle data. In this aspect, the vehicle network 114 may be a Controller Area Network (CAN), On-Board Diagnostics Generation Two (ODB-II), Ethernet, and/or other communication interfaces.

In this aspect, the battery monitor 104 may comprise a voltage sensor 204 providing one or more voltage measurements (e.g., voltage data), and/or a current sensor 206 providing one or more current measurements (e.g., current data). The current sensor 206 may be placed in series with the main wiring 208 of the heavy machine 120 and the voltage sensor 204 may be placed in parallel with the battery 102, such as coupled to battery terminals or across the electric load(s). The current sensor 206 may provide current data 216 to an interface 202 of the controller 106. Likewise, the voltage sensor 204 may provide voltage measurements 212 to the interface 202. In some aspects, the voltage may be determined from the vehicle electronic system 108 by the interface 202. In other aspects, the voltage may be entered by the operator. In this aspect, the current sensor 206 and/or the voltage sensor 204 comprise an analog-to-digital converter that converts one or more analog measurements into digital measurements. The interface 202 may receive vehicle data via the vehicle network 114. The interface 202 may store the current data 216, the voltage data 212, and/or the vehicle data in a computer-readable memory for retrieval by the controller 106.

The controller 106 may communicate the vehicle data 114, the voltage data 212, the current data 216, and/or any processed data to the server 110, or vice-versa over the communication system 218. The controller 106 and/or the server 110 may process the vehicle data 114, the voltage data 212, the current data 216 to determine one or more tasks. The process 500 may be described in further detail with reference to FIGS. 4 and 5 below.

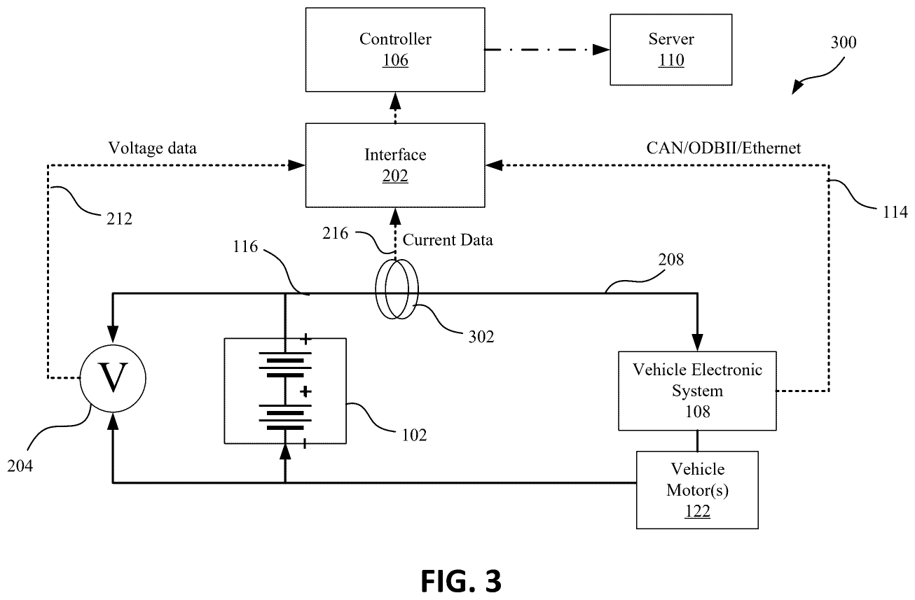

In yet another aspect shown in FIG. 3, there is provided another energy usage monitoring system 300 for measuring and tracking battery data from the heavy machine 120. Similar to that of FIG. 2, the heavy machine 120 may comprise the vehicle battery 102 providing electricity to the vehicle motors 122 and being periodically charged from the energy source 124. The vehicle electronic system 108 may monitor the vehicle motors 122, vehicle battery 102, and/or other vehicle parameters for the heavy machine 120. The vehicle electronic system 108 may provide the vehicle network 114 to provide vehicle data. In this aspect, the vehicle network 114 may be a Controller Area Network (CAN), On-Board Diagnostics Generation Two (ODB-II), Ethernet, and/or other communication interfaces.

In this aspect, the battery monitor 104 may comprise a voltage sensor 204 and/or a hall-effect sensor 302. For example, the hall-effect sensor 302 may be placed around one of these main wires 208. In some aspects, the hall-effect sensor 302 may be a hinged-style sensor which may be connected to the wire 208 without disconnecting the wire 208. The hall-effect sensor 302 may be a hall-effect current sensor that measures a strength of a magnetic field produced by an amount of current that is flowing through the wire 208. The voltage sensor 204 may be placed in parallel with the battery 102. The hall-effect sensor 302 may provide current data 216 to the interface 202 of the controller 106. Likewise, the voltage sensor 204 may provide voltage data 212 to the interface 202. In this aspect, the current sensor 206 and/or the voltage sensor 204 comprise an analog-to-digital converter that converts one or more analog measurements into digital measurements. The interface 202 may receive vehicle data via the vehicle network 114. The interface 202 may store the current data 216, the voltage data 212, and/or the vehicle data in a memory for retrieval by the controller 106.

The controller 106 may communicate the vehicle data 114, the voltage data 212, the current data 216, and/or any processed data to the server 110, or vice-versa over the communication system 218. The controller 106 and/or the server 110 may process the vehicle data 114, the voltage data 212, the current data 216 to determine one or more tasks. The process 500 may be described in further detail with reference to FIGS. 4 and 5 below.

Turning to FIGS. 4 and 5, a controller process 402 may configure the controller 106 to perform a number of processes and/or execute one or more instructions from a computer-readable memory. The controller process 402 retrieves the battery data 112 and the vehicle data 114. The controller process 402 may then process the battery data 112 and the vehicle data 114 according to a process 500 detailed in FIG. 5. The controller process 402 may then transmit the processed data to the server 110. The server 110 may then log, analyze, and/or trigger notifications and alerts based on the processed data. The server 110 may be an on-site or a cloud-based server.

The process 500 may monitor a battery capacity at step 502 from the battery data 112 and/or the vehicle data 114. For example, the vehicle data 114 may provide a percentage of battery capacity. At step 504, when a change in the battery capacity occurs, the controller 106 may determine that a task has been initiated, which then proceeds to step 506. Otherwise, the process 500 returns to the monitoring battery capacity step 502. In some aspects, the operator may identify a task name, task type, and/or the task start on a user interface provided on a display by the controller 106. The change in the battery capacity may be determined by a change in the percentage of battery capacity retrieved from the vehicle data 114, determining a change in the voltage data 212, and/or determining a change in the current data 216. In some aspects, position may determine the start and end of tasks such as entering and exiting the charge bay and/or other location.

When the task is initiated, a start of the task is set at step 506. In some aspects, the start of the task is recorded when the change in the battery capacity and/or the change in the current data 216, such as exceeding a threshold amount. Other aspects may determine the start of the task based on a proximity to a waypoint, an input device, one or more sensors, a heavy machine schedule, and/or analysis of current data. The proximity may be determined based on a work area size. The analysis of the current data may involve identifying one or more characteristics of the load based on a current consumption. The recording of the start of the task at step 506 may involve recording a start time and a starting battery capacity. The battery capacity during the task may then be monitored at step 508. During step 508, the current data, the voltage data, and/or the battery charge may be recorded to the memory based on a sample rate while the task is performed.

When the change in the battery capacity falls below a threshold, the controller 106 may determine that the task has ended (i.e. task completion) at step 510. Other aspects may determine the end of the task based on a proximity to a waypoint, an input device, one or more sensors, and/or analysis of current data. The proximity may be determined based on a work area size. For example, the task may end when the machine 120 movies from a mine face to an ore chute. In another example, the task may end when the machine 120 moves to the charging station. The analysis of the current data may involve identifying one or more characteristics of the load based on a current consumption. In some aspects, the end of the task may be determined by a schedule, such as an end of a shift. When the change in the battery capacity is above the threshold, the process 500 returns to step 508 to continue recording the current data, the voltage data, and/or the battery charge. In other aspects, the operator may indicate a stop point on the user interface provided on the display by the controller 106. Other aspects may determine the end of the task based on proximity to a waypoint, the input device, one or more sensors, and/or analysis of the current data. The proximity may be determined based on a work area size. The analysis of the current data may involve identifying one or more characteristics of the load based on a current consumption. When the task has ended, the end of the task is recorded at step 512. The recording of the end of the task may involve recording an end time and an end battery capacity.

The process 500 may then proceed to determining a capacity of the task at step 514. In some aspects, the capacity of the task may be determined based on the drop in the battery capacity from the task start to the task end, which may be a starting percentage and an ending percentage. The operator may enter a total capacity of the battery to determine a power used to perform the task. For example, when a battery has a capacity of 50 kWh and the task used 20% of the battery capacity, the task capacity is approximately 10 kWh.

In another aspect, the current data and the voltage data may determine the amount of energy consumed to perform the task. For example, the current data comprises instantaneous current measurements taken over the task duration. These instantaneous current values may be multiplied by the voltage data to provide an instantaneous power over the task duration. The instantaneous power values may be summed to provide a total energy consumed during the task. The total energy consumed may be calculated using numerical integration methods, such as the Trapezoidal Rule, Simpson's Rule, Midpoint Rule, Romberg Integration, Gaussian Quadrature, Monte Carlo Integration, Adaptive Quadrature, Newton-Cotes Formulas, and/or other such numerical integration methods. In another aspect, the voltage data may determine an amount of charge remaining in the battery 102 based on the battery discharge curve.

In some aspects, the systems 100, 200, 300 described herein may further comprise one or more additional sensors. For example, a temperature sensor may provide temperature data to the controller 106 for recording to memory and/or triggering notifications for display on the user interface. In this example, the temperature sensor may be installed on or near the battery, such as near one or more faces of the battery, such that the temperature measurements generally indicate a battery temperature. In another example, an accelerometer, a position sensor (e.g., a global positioning sensor, i.e., GPS), and/or a tilt sensor may be coupled to the heavy machine 120 to measure a movement of the heavy machine 120. Such position, velocity, and/or orientation measurements may provide task data to the controller 106 and be used to determine the start of the task, the end of the task, and/or a number of repetitions of the task.

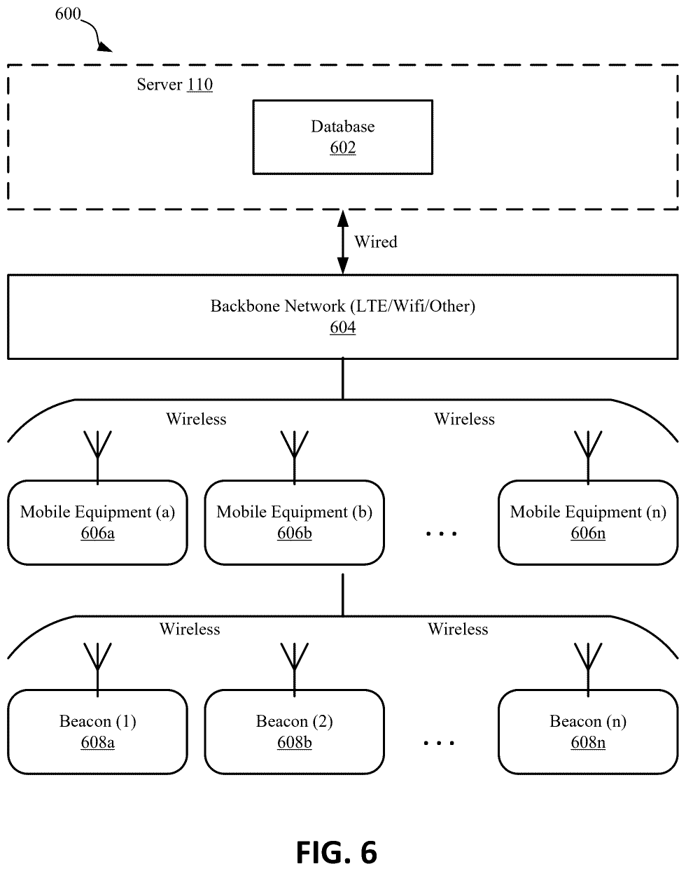

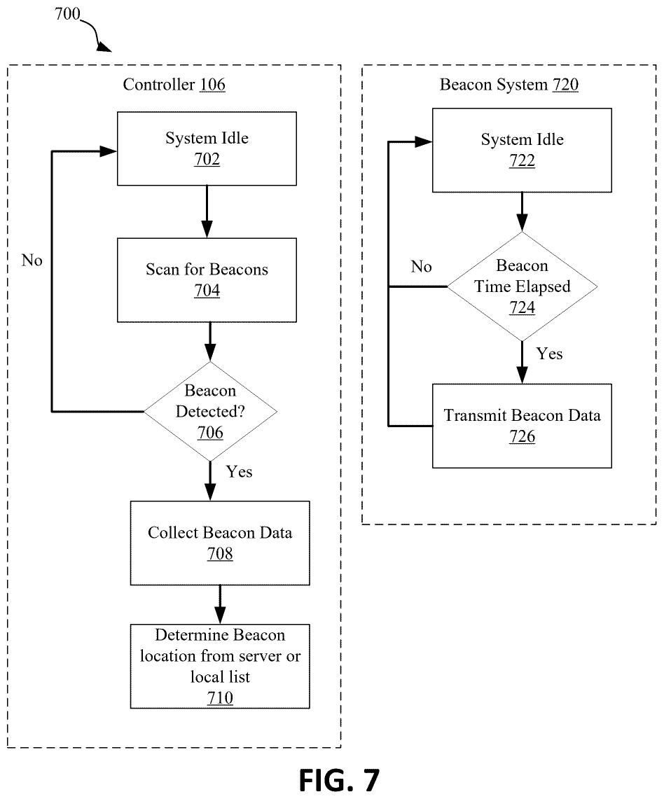

In some aspects shown particularly in FIGS. 6-7, a tracking system 600 may comprise the server 110, a network backbone 604, one or more mobile equipment 606, and/or one or more beacons 608. The server 110 may store a database 602 of tasks and the energy consumed to perform each of the tasks. The database 602 may also store a type of the heavy machine 120 performing the task. The server 110 may communicate with a network backbone 604 via a wired connection. In this aspect, the server 110 may be located at or above the surface. The network backbone 604, mobile equipment 606a, 606b . . . 606n (collectively referred to as 606 herein), and/or beacons 608a, 608b, . . . 608n (collectively referred to as 608 herein) may be located below the surface (e.g., within the mine). The network backbone 604 may communicate with the controllers 106 on the mobile equipment 606 via one or more wireless connections (e.g., LTE, Wifi, and/or other wireless communication). The controller 106, on the mobile equipment 606, may retrieve a set of tasks from the server 110 for the type of the heavy machine 120. The controller 106 may display the set of tasks in the user interface on the display on the mobile equipment 606. When the operator selects one of the tasks, the controller 106 may determine the amount of charge in the battery 102 and may determine the number of tasks that may be performed, such as dividing the amount of charge in the battery 102 by the amount of energy associated with the selected task. The number of tasks may then be displayed on the user interface.

In some aspects, the controller 106 may track whether the battery 102 has sufficient charge to complete a task and/or a series of tasks to complete a shift or segment of work. For example, the task may have been performed in the past, such as travel between two waypoints. The controller 106 may recognize the task that the heavy machine 120 is about to perform based on past historical data from the server 110. For example, the controller 106 may detect that the heavy machine 120 passes by a particular location or route and determine that the heavy machine 120 is travelling to a particular end point before returning to a starting point. The controller 106 may determine, based on historical data and/or current data, such as data representing a current location, a type of task being performed, whether the battery 102 has sufficient charge to complete the task. When the controller 106 determines that the battery 102 may experience an out-of-charge condition during the current task, an alert notification may be generated.

For example, the task may be a number of trips between two or more waypoints. In this aspect, the waypoints may be associated with one or more of the beacons 608. The controller 106 may then display the number of trips remaining on the user interface. The number of trips may be a representation of the number of times that the heavy machine 120 may be expected to travel, either one way, or round-trip, between two or more waypoints. These waypoints may be automatically determined by the controller 106 as shown in FIG. 7. The controller 106 may execute a process 700 that starts in an idle mode 702. Periodically, the controller 106 performs a scanning process 704 that scans for one or more beacons 608. When the beacons 608 are detected 806, the controller 106 may collect beacon data from the beacon 608 in a collection process 708. In some aspects, the scanning process 704 determines a closest beacon 608 to the mobile equipment 606. In other aspects, the scanning process 704 may determine a few beacons 608 and may perform a wireless triangulation of a position of the mobile equipment 606. In yet another aspect, the controller 106 may, at step 710, request a beacon location from the server 110 or may lookup the beacon location from a local list of beacons 608.

Each of the beacon systems 720 may execute an idle process 722. According to a beacon timer, the beacon system 720 determines when the beacon time elapses 724. When the beacon time elapses 724, the beacon 608 may transmit beacon data at step 726, which may be received by one or more controllers 106 within the mobile equipment 606.

In other aspects, the controller 106 may determine the waypoints based on the sensor data and/or user input data. For example, the controller 106 may receive operator input from the user interface, such as a pushbutton, which the operator may use to indicate when the heavy machine 120 is at one of the waypoints. In some aspects, the controller 106 may determine the waypoints using the sensor data. The sensor data may include, for example, location sensor data, such as GPS data and/or cellular triangulation data. The sensor data may include, for example, tilt or acceleration sensor data, such as data that may be generated by one or more accelerometers. The sensor data could also include, for example, altimeter data. The sensor data may be used in a breadcrumb tracking system such that a “bread crumb” or waypoint may be placed along a path when the sensor data changes according to criteria. For example, a waypoint may be placed when the altimeter data reaches a minimum within a mine indicating that an end of the path is reached.

The method of detecting the waypoints may depend on the type of heavy machine 120 and/or the function of the heavy machine 120. For example, the heavy machine 120 that is used only above ground may rely on a location sensor, such as GPS sensor. The heavy machine 120 that may be used below ground may rely on other sensor data, such as the altimeter. A lowest point on an altimeter may generally be determined to represent one waypoint (which may be down mine) and a highest point may represent another waypoint (which may be up mine). The accelerometer and/or other tilt sensor may also be used to determine whether the heavy machine 120 is travelling downhill (e.g., down mine) or uphill (e.g., up mine) and the waypoints may be determined based, at least in part, on such data.

Once the waypoints have been determined, the controller 106 may determine the number of trips that are remaining (i.e., remaining tasks) by determining the amount of charge typically consumed for each leg of the trip (i.e., task charge) between those waypoints similar to determining the number of tasks as previously described. The amount of task charge consumed may be different based on a direction of the trip. For example, less charge may be consumed going downhill into a mine than uphill. The controller 106 may separately track the amount of charge used for travel between the waypoints in each direction. The amount of charge consumed for each leg of the trip may be determined from historical data retrieved from the database stored on the server 110.

Based on the current state of charge, and the amount of charge consumed for the legs of the trip, the controller 106 may determine the number of trips remaining. In some implementations, the controller 106 may report the number of trips in terms of the number of upward trips and the number of downward trips. The number of trips remaining may be displayed to the operator via the user interface. For example, a display screen may be provided on the heavy machine 120 or via an application executing on a mobile device (not shown), which may list the number of trips remaining.

In some aspects, one of the tasks may be a charging task. Based on the current data and the voltage data, the controller 106 may determine a state of charge of the battery. For example, the controller 106 may determine when a battery has been charged by monitoring an amount of current entering the battery 102.

According to an aspect, the controller 106 may provide one or more notifications to the operator on the user interface in response to the current data, the voltage data, and/or the vehicle data. For example, when the controller 106 determines that the battery 102 may completely run out of charge such that the heavy machine 120 is unable to return to a charging station, the controller 106 may provide a notification to the operator to return the heavy machine 120 to the charging station. The out-of-charge condition may be detected by the controller 106 based on the battery charge monitor 104 as previously described.

The controller 106 may store an indicator of a charge amount that is required to reach the charging station (e.g. resurface from the depth of the mine). The controller 106 may determine the charge amount based on historical data. For example, the amount of charge required to ascend may be determined by monitoring the state of charge of the battery 102 from the battery charge monitor 104. The heavy machine 120 begins to ascend and as the heavy machine 120 reaches the altitude associated with ground level, the delta between current level and the ground level represents the amount of charge to ascend.

In an aspect, the controller 106 may detect that heavy machine 120 may run out of charge as the heavy machine 120 is expected to be charged at a start of a shift. When controller 106 determines that the battery 102 has not been charged at the start of the shift, the controller 106 may determine that the heavy machine 120 may run out of charge during operation. The controller 106 may detect when the battery 102 is not charged at the start of a shift by determining when the charge of the battery 102 has not increased prior to a pre-defined time that is associated with the start of a shift. The controller 106 may communicate any out-of-charge conditions at the start of the shift to the server 110. The server 110 may generate a notification to a maintenance computer (not shown) when the out-of-charge conditions at the start of the shift exceed a predetermined threshold.

In another aspect, the controller 106 may detect that the battery 102 may run out of charge when the amount of charge remaining is less than an amount that is expected to be required to return the heavy machine 120 plus possibly including reserving a buffer amount for safety. For example in a mining application, the controller 106 may determine that the heavy machine 120 is underground using a variety of techniques. For example, the altimeter may be used and historical data may be used to determine the maximum altitude that the heavy machine 120 typically travels. The maximum altitude may be considered to be an above ground altitude. When the current altitude of the heavy machine 120 is less than the maximum altitude, the heavy machine 120 may be considered to be below ground. In another example, the controller 106 may be calibrated using an input device to indicate when the heavy machine 120 is at ground level and/or at the charging station. In some aspects, the controller may be determined to be at a charging station when at a particular altitude associated with the charging station. In yet another example, the controller 106 may determine that the heavy machine 120 is not proximate to the charging station when the controller 106 is out of direct communication range of an above-ground communication system.

In another example, the controller 106 may check whether the battery 102 has sufficient charge to both descend and ascend when the heavy machine 120 is detected to have begun a decent. When the controller 106 determines that the battery 102 may not have enough charge to make the round trip, the controller 106 may trigger a notification for the operator (e.g., audio and/or visual indicator). The controller 106 may determine that the heavy machine 120 has begun the decent using the altimeter, or the tilt sensor which may detect a tilt of the heavy machine 120 associated with a decent, etc.

In another example, the controller 106 may check whether the battery 102 has sufficient charge to complete a task with the heavy machine 120. When the charge drops below a threshold to perform the task, the controller may trigger a notification for the operator.

In some aspects, the controller 106 may track a current location of the heavy machine 120 and may generate alerts based on the current location being within range of a set of locations. For example, in some mines, the heavy machine 120 may remain underground and may not proceed above ground and the controller 106 may monitor the current location and generate an alert when the controller 106 detects the current location being too far from a charging station for the current state of charge within the battery 102. The current location may be determined, for example, using one or more beacons 608. For example, the beacons 608 may be deployed at one or more locations in a mine and the controller 106 on the mobile equipment 606 may determine the current location using the beacons 608. At least one of the beacons 608 may be located at or near a charger. In some aspects, the beacons 608 may be WiFi access points (e.g. WiFi Beacon) that may be detected by a WiFi receiver coupled to the controller 106. In other aspects, the beacons 608 may be any type of wireless transceiver, such as WiFi, Bluetooth, ISM band, LoRa, etc.

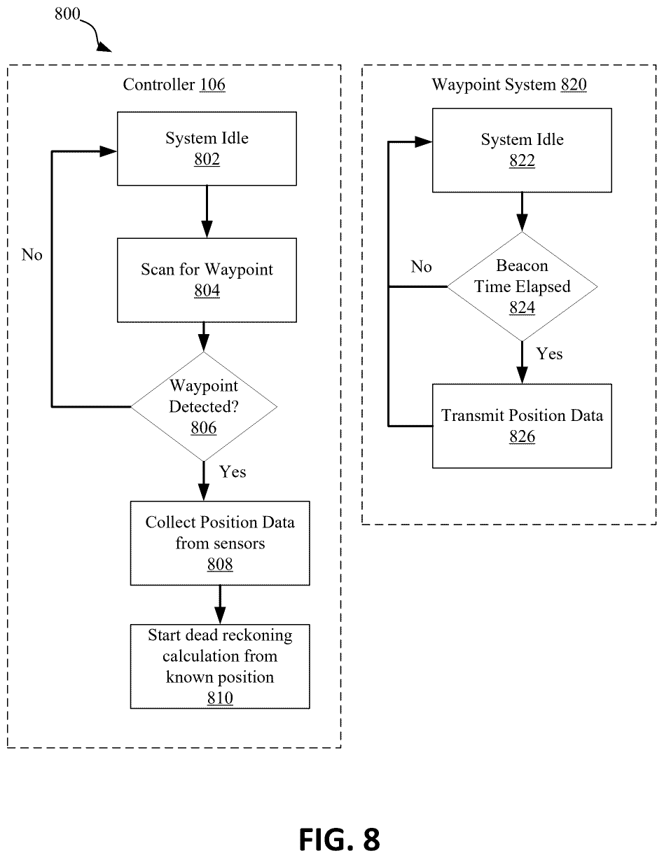

In another example shown particularly in FIG. 8, a dead reckoning system 800 may be used to track the current location. The controller 106 may remain in an idle state 802 and periodically may perform a scanning process 804 for a waypoint. When a waypoint is detected 806, the controller 106 may receive or collect sensor data at step 808 from a plurality of sensors, such as accelerometers, magnetometers (to get directional data), and/or altimeters. The controller 106 may determine the current location using a dead reckoning calculation from a known position at step 810. For example, the altimeter data may be used to determine a level of the heavy machine 120 or, depending on how unique the altitude is, a location of the heavy machine 120. In some aspects, a waypoint system 820 may comprise a single beacon 608 deployed at the charging station which may provide a starting location from which dead reckoning may be used to determine the current location after movement of the heavy machine 120 away from the beacon 608.

The waypoint system 820 may remain in an idle state 822 until a beacon time has elapsed at step 824. The beacon 608 may then transmit position data 826 that may be received by the controller 106.

In some aspects, the controller 106 may be situated on the heavy machine 120 or off the heavy machine 120. The current data, the voltage data, the sensor data, and/or the vehicle data may be transmitted continuously and/or periodically from the battery monitor 104 and/or the vehicle electronic system 108 via a transmitter wired and/or wirelessly.

The aspects described herein may be integrated into the heavy machine 120 when the heavy machine 120 was manufactured. Other aspects may include a retrofit kit for coupling to previously manufactured heavy machine 120. The retrofit kit may include an antenna to be installed on an exterior side of the heavy machine 120 and that may be used for communication. Other aspects may have the antenna installed on an interior side of the heavy machine 120.

Although the aspects herein refer to a heavy machine, the techniques described herein may apply to any type of electric machine.

Although the aspects herein refer to an energy storage as comprising a rechargeable battery, the aspects herein may apply to any rechargeable energy storage. For example, the rechargeable battery may be a Lithium-ion (Li-ion), Lead-acid, Nickel-cadmium (Ni—Cd), Nickel-metal hydride (Ni—MH), Sealed Lead-acid, Iron Phosphate (FePO₄), and/or any combination thereof. In other aspects, the rechargeable energy storage may comprise one or more capacitors and/or an inductors.

Although the aspects herein demonstrate a single battery monitor 104 associated with a single battery 102, other aspects may have a plurality of batteries 102 with each having a battery monitor 104. In this aspect, the battery monitors 104 may determine the collective charge usage of the task by combining the measurements of each of the battery monitors 104. Other aspects may determine which of the batteries 102 may become depleted first out of the plurality of batteries 102 to determine the number of remaining tasks.

Although the aspects herein demonstrate a single controller 106 associated with a single battery monitor 104, other aspects may have a plurality of battery monitors 104 providing current measurements and/or voltage measurements to the controller 106. The controller 106 may act as a central hub providing the measurements and/or power usage from the battery monitors 104 and/or vehicle electronic system 108 to the server 110. Other aspects may have a plurality of controllers 106 each controller 106 corresponding to one of the plurality of battery monitors 104. The plurality of controllers 106 may provide their respective measurements and/or power usage to a central controller, which provides the measurements to the server 110.

Although the aspects herein refer to a vehicle electronic system 108, the vehicle electronic system 108 may comprise one or more battery management systems or battery data systems.

In some aspects, the controller 106 may use machine learning or other techniques to predict a current location for a given time of day.

Although the aspects herein refer to the controller 106, the use of the term is not intended to be limiting. Other processors or computing structures may be used, such as a digital signal processor (DSP), microcontroller, multi-core processor, single-core processor, etc.

The above-described embodiments are intended to be examples and alterations and modifications could be affected thereto, by those of skill in the art, without departing from the scope, which is defined solely by the claims appended hereto.

What is claimed is:

1. A system for reporting a state of charge of an electric machine during a task, the system comprising:
a battery monitor coupled to a battery, the battery monitor measuring a battery charge in the battery;
a processor coupled to the battery monitor, the processor configured to execute instructions from a computer-readable memory to:
determine a change in the battery charge for a duration of the task to provide a task charge; and
determine a number of remaining tasks from the battery charge and the task charge.

2. The system according to claim 1, wherein the task is travel between at least one waypoint.

3. The system according to claim 2, wherein the task charge is different depending on a direction travelled from or to the at least one waypoint.

4. The system according to claim 1, wherein a sensor is selected from at least one of: a global positioning sensor (GPS), at least one magnetometer, a cellular triangulation, an altimeter, a tilt sensor, a wireless receiver and at least one wireless beacon, and at least one accelerometer.

5. The system according to claim 1, wherein the instructions further comprise:
reserving a reserve of the battery charge so that the electric machine reaches a charging station on a task completion.

6. The system according to claim 1, wherein the battery monitor comprises at least one of: a current sensor measuring at least one current measurement; and a voltage sensor measuring at least one voltage measurement.

7. The system according to claim 6, wherein the current sensor measures the at least one current measurement without disconnecting the battery.

8. The system according to claim 7, wherein the at least one current sensor is a hall-effect sensor.

9. The system according to claim 6, further comprising a server computer system receiving at least one of: a task type, the duration, the at least one current measurement, the at least one voltage measurement, and the task charge from the processor.

10. The system according to claim 6, further comprises computing a power from the at least one current measurement and the at least one voltage measurement; and integrating the power for the duration.

11. The system according to claim 1, wherein the processor determines the number of the remaining tasks based on the task charge of a plurality of tasks.

12. A method for reporting a state of charge of an electric machine, the method comprising:
measuring a battery charge using a battery monitor coupled to a battery;
determining a change in the battery charge during a task to provide a task charge; and
determining a number of remaining tasks from the battery charge and the task charge.

13. The method according to claim 12, wherein the task is travel from or to at least one waypoints.

14. The method according to claim 13, wherein the task charge is different depending on a direction travelled to or from the at least one waypoint.

15. The method according to claim 12, further comprises determining a duration of the task using a sensor or an input device; the sensor is selected from at least one of: a global positioning sensor (GPS), at least one magnetometer, a wireless triangulation, an altimeter, a tilt sensor, a wireless receiver and at least one wireless beacon, and at least one accelerometer.

16. The method according to claim 12, further comprise: reserving a reserve of the battery charge for the electric machine to reach a charging station.

17. The method according to claim 15, wherein the battery monitor comprises at least one of: a current sensor measuring at least one current measurement; and a voltage sensor measuring at least one voltage measurement.

18. The method according to claim 17, wherein the current sensor measures the at least one current measurement without disconnecting the battery.

19. The method according to claim 18, wherein the current sensor is a hall-effect sensor.

20. The method according to claim 17, further comprising a server computer system receiving at least one of: a task type, the duration, the at least one current measurement, the at least one voltage measurement, and the task charge.
